(19) United States
(12) Patent Application Publication
(10) Pub. No.: US 2008/0180878 A1
(43) Pub. Date: Jul. 31, 2008

(54) PACKAGE STRUCTURE WITH EMBEDDED CAPACITOR, FABRICATING PROCESS THEREOF AND APPLICATIONS OF THE SAME

(75) Inventors: Yung-Hui Wang, Kaohsiung City (TW); Ying-Te Ou, Kaohsiung (TW); Chih-Pin Hung, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/942,487

(22) Filed: Nov. 19, 2007

(30) Foreign Application Priority Data
Jan. 31, 2007 (TW) 96103594

(51) Int. Cl. H01L 21/283; H01G 4/228

(52) U.S. Cl. 361/306.3; 438/396; 257/E21.159

(57) ABSTRACT

A package structure with an embedded capacitor, a fabricating process thereof and applications of the same are provided, wherein the package structure includes a dielectric layer, a first conductive layer, a second conductive layer, a first embedded plate and a second embedded plate. The dielectric layer has a thickness. The first conductive layer with a first potential is located on one side of the dielectric layer. The second conductive layer with a second potential is located on the dielectric layer at the other side thereof opposite to the first conductive layer. The first embedded plate and the second embedded plate that are embedded in the dielectric layer are separated at a distance, wherein the first embedded plate is electrically connected with the first conductive layer, and the second embedded plate is electrically connected with the second conductive layer.

### CROSS-REFERENCE TO RELATED APPLICATION

This application claims the priority benefit of Taiwan application serial no. 96103594, filed on Jan. 31, 2007. The entirety of the above-mentioned patent application is hereby incorporated by reference herein and made a part of this specification.

### BACKGROUND OF THE INVENTION

1. Field of the Invention

The present invention relates to a package structure and a fabricating process thereof, and in particular, to a package structure with an embedded capacitor, a fabricating process thereof and applications of the same.

2. Description of Related Art

A package structure with an embedded capacitor is a package structure which embeds the capacitor in a substrate with a dielectric material by using a Multiple Stacked Package (MSP) technology, thereby replacing a conventional non-embedded ceramic capacitor for shortening a circuit layout and reducing a required number of non-embedded passive devices, so as to reduce a distance of signal transmission for improving the working performance of an entire package structure.

A conventional embedded capacitor device is mainly classified into a Metal-Insulator-Metal (MIM) capacitor and a Vertically-Interdigitated-Capacitor (VIC) capacitor, wherein the MIM capacitor is a capacitor structure formed by using two metal panels respectively disposed on an upper side and a lower side of a dielectric layer, while the VIC capacitor is formed by many metal flat boards which are alternately stacked.

However, because a capacitor property (a capacitor value) of the capacitor device is proportional to a dielectric constant of the dielectric material of the device, the dielectric material of the conventional embedded capacitor device cannot go through a high temperature sintering process as the non-embedded ceramic capacitor (usually a strontium titanate group material formed by performing the high temperature sintering process) does; therefore, the dielectric constant of the conventional embedded capacitor is usually smaller than that of the non-embedded ceramic capacitor, and thereby the capacitor property of the conventional embedded capacitor is inferior to that of the non-embedded ceramic capacitor. Even replacing the dielectric material of the conventional embedded capacitor with a polymer/ceramic-powder compound material, the dielectric constant of the conventional embedded capacitor is still smaller than that of a conventional separated-type ceramic capacitor.

In order to improve the capacitor property of the embedded capacitor device, it is needed to increase the number of the stacked capacitor structures in the aforesaid two kinds of capacitor devices; however, by doing so, not only a limited layout space of the substrate is occupied, but also a thickness of the substrate increases significantly.

### SUMMARY OF THE INVENTION

Therefore, an advanced package structure with an embedded capacitor and a fabricating process thereof are demanded desperately, which can enhance the capacitor property of the embedded capacitor without increasing the thickness of the substrate, thereby solving the problem that the thickness of the substrate significantly increases for enhancing the capacitor property in the embedded capacitor device.

The present invention is directed to a package structure with an embedded capacitor. The package structure with the embedded capacitor includes a dielectric layer, a first conductive layer, a second conductive layer, a first embedded plate and a second embedded plate. The dielectric layer has a thickness. The first conductive layer is at one side of the dielectric layer and has a first potential. The second conductive layer is disposed at the other side of the dielectric layer. The second conductive layer is opposite to the first conductive layer and has a second potential. The first embedded plate is embedded in the dielectric layer and is electrically connected with the first conductive layer. The second embedded plate is embedded in the dielectric layer, electrically connected with the second conductive layer and separated from the first embedded plate at a distance.

The present invention is further directed to a core layer of a package structure. The core layer of the package structure comprises: a dielectric layer, a first conductive layer, a second conductive layer, a first embedded plate and a second embedded plate. The dielectric layer has a thickness. The first conductive layer which has a first potential is disposed at one side of the dielectric layer. The second conductive layer which has a second potential is disposed on the dielectric layer at the other side thereof opposite to the first conductive layer. The first embedded plate is embedded in the dielectric layer and is electrically connected with the first conductive layer. The second embedded plate is embedded in the dielectric layer, electrically connected with the second conductive layer and separated from the first embedded plate at a distance.

The present invention is further directed to a fabricating process of a package structure with an embedded capacitor. The fabricating process includes steps as follows.

A dielectric layer is provided at first. Then, a first surface of the dielectric layer is patterned for forming a first groove recessed in the dielectric layer. Next, a first conductive layer is formed on the first surface and the first groove is filled with the first conductive layer. After that, a second surface of the dielectric layer is patterned for forming a second groove recessed in the dielectric layer, wherein the second surface is opposite to the first surface and is separated from the first groove at a distance. Thereafter, a second conductive layer is formed at the second surface and the second groove is filled with the second conductive layer.

The present invention is still directed to a fabricating process of a package structure with an embedded capacitor. The fabricating process includes steps as follows.

A core layer is provided at first, wherein the core layer includes a substrate, a first conductive layer disposed on one side of the substrate, and a second conductive layer which is disposed on the substrate at the other side thereof opposite to the first conductive layer. Next, a first groove is formed on the first conductive layer and the first groove is recessed in the substrate. Then, a second groove is formed on the second conductive layer and is recessed in the substrate. The first groove is separated from the second groove at a distance. Thereafter, the first groove and the second groove are filled with a conductive material.

The present invention is further directed to a fabricating process of a package structure with an embedded capacitor. The fabricating process includes steps as follows.

A Resin Clad Copper (RCC) layer is provided at first, wherein the RCC layer includes a substrate and a copper film which is disposed at one side of the substrate. Next, a first groove is formed on the copper film and is recessed in the substrate. Then, the first groove is filled with a conductive material. After that, a second groove is formed and recessed in the substrate at the other side thereof opposite to the copper film. The first groove is separated from the second groove at a distance. Thereafter, a second conductive layer is formed on the substrate at the other side thereof opposite to the copper film, and the second groove is filled with the second conductive layer.

According to one embodiment of the present invention, the techniques of the present invention are characterized in that the two grooves respectively disposed at the opposite sides of the dielectric layer are filled with the conductive material for forming two conductive embedded plates embedded in the dielectric layer correspondingly, and the package structure with the embedded capacitor can be formed by the two conductive embedded plates which have opposite potentials, and by the dielectric layer disposed between the two conductive embedded plates. By adopting the package structure with the embedded capacitor, even the number of the embedded plates increases, the number of the aforesaid stacked package structures does not increase. Accordingly, the thickness of the package structure with the embedded capacitor does not increase, thereby solving the problem that the thickness of the package structure with the embedded capacitor has to be increased for improving the working performance of the package structure with the embedded capacitor. Furthermore, a circuit layout in the package structure is also shortened, so as to save a circuit-layout space and to reduce a distance of signal transmission.

### BRIEF DESCRIPTION OF THE DRAWINGS

In order to make the aforementioned and other objects, features and advantages of the present invention more comprehensible, embodiments accompanied with figures are described in detail below.

FIG. 1 illustrates a package structure 100 with an embedded capacitor according to one embodiment of the present invention.

FIG. 2 is a cross-sectional view illustrating a package structure of an interlayer circuit board 200 having the package structure 100 with the embedded capacitor according to one embodiment of the present invention.

FIG. 3 is a cross-sectional view illustrating a package structure of a multi-layered circuit board 300 having the package structure 100 with the embedded capacitor according to another embodiment of the present invention.

FIGS. 4A-4D are cross-sectional views illustrating a processing flow for fabricating a package structure 400 with an embedded capacitor according to one embodiment of the present invention.

FIGS. 5A-5D are cross-sectional views illustrating another processing flow for fabricating a package structure 500 with an embedded structure according to one embodiment of the present invention.

FIGS. 6A-6D are cross-sectional views illustrating still another processing flow for fabricating a package structure 600 with an embedded structure according to one embodiment of the present invention.

### DESCRIPTION OF EMBODIMENTS

The embodiments of the present invention are directed to a package structure with an embedded capacitor. In order to make the aforementioned and other objects, features and advantages of the present invention more comprehensible, embodiments of several package structures with embedded capacitors are described in detail below.

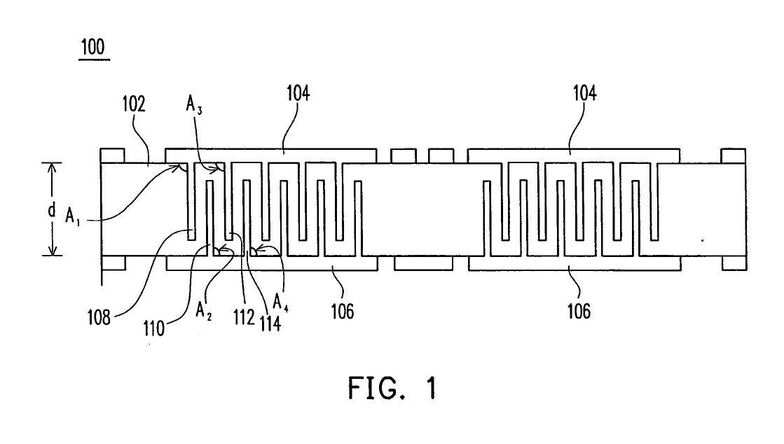

Please refer to FIG. 1 which illustrates a package structure 100 with an embedded capacitor according to one embodiment of the present invention. The package structure 100 with the embedded capacitor includes: a dielectric layer 102, a first conductive layer 104, a second conductive layer 106, a first embedded plate 108, and a second embedded plate 110. The dielectric layer 102 has a thickness d. In one embodiment of the present invention, the dielectric layer 102 can be a resin substrate in a Resin Clad Copper (RCC) layer. However, in a different embodiment, the dielectric layer 102 is a core dielectric layer in an interlayer circuit board.

The first conductive layer 104 is at one side of the dielectric layer 102 and has a first potential. In one embodiment of the present invention, the first conductive layer 104 is a patterned copper film covering the RCC layer. However, in another embodiment, the first conductive layer 104 can be a conductive circuit layer covering the core layer of the interlayer circuit board.

The second conductive layer 106 is a conductive circuit layer disposed on the dielectric layer 102 at the other side thereof opposite to the first conductive layer 104, and has a second potential.

The first embedded plate 108 is embedded in the dielectric layer 102 and is electrically connected with the first conductive layer 104. The second embedded plate 110 is embedded in the dielectric layer 102, electrically connected with the second conductive layer 106 and separated from the first embedded plate 108 at a distance.

In one embodiment of the present invention, the first embedded plate 108 and the second embedded plate 110 are respectively embedded in the dielectric layer 102 with a length which is substantially greater than half of the thickness d of the dielectric layer 102. The first conductive layer 104 and the first embedded plate 108 form a first included angle A₁, which is substantially greater than 0 degree and smaller than 180 degrees. The first included angle A₁ is preferably 90 degrees. The second conductive layer 106 and the second embedded plate 110 form a second included angle A₂ which is substantially greater than 0 degree and smaller than 180 degrees. The second included angle A₂ is preferably 90 degrees, so the first embedded plate 108 is preferably parallel to the second embedded plate 110.

In practice, in order to enhance the capacitor property of the package structure 100 with the embedded capacitor, it is required to increase the number and the density of the embedded plates. Therefore, in one embodiment of the present invention, the package structure 100 of the embedded capacitor further includes a third embedded plate 112 and the fourth embedded plate 114 embedded in the dielectric layer.

The third embedded plate 112 is embedded in the dielectric layer 102 and is electrically connected with the first conductive layer 104. The second embedded plate 110 is disposed between the first embedded plate 108 and the third embedded plate 112, and the three embedded plates are separated from one another at a distance. A fourth embedded plate 114 is embedded in the dielectric layer 102 and is electrically connected with the second conductive layer 106, wherein the third embedded plate 112 is disposed between the second embedded plate 110 and the fourth embedded plate 114, and the three embedded plates are separated from one another at a distance.

The third embedded plate 112 and the fourth embedded plate 114 are respectively embedded in the dielectric layer 102 with a length which is greater than half of the thickness d of the dielectric layer 102. The first conductive layer 104 and the third embedded plate 112 form a third included angle A₃ which is substantially greater than 0 degree and smaller than 180 degrees. The third included angle A₁ is preferably 90 degrees. The second conductive layer 106 and the fourth embedded 114 form a fourth included angle A₄ which is substantially greater than 0 degree and smaller than 180 degrees. The fourth included angle A₄ is preferably 90 degrees. Therefore, the first embedded plate 108, the second embedded plate 110, the third embedded plate 112 and the fourth embedded plate 114 are parallel to one another.

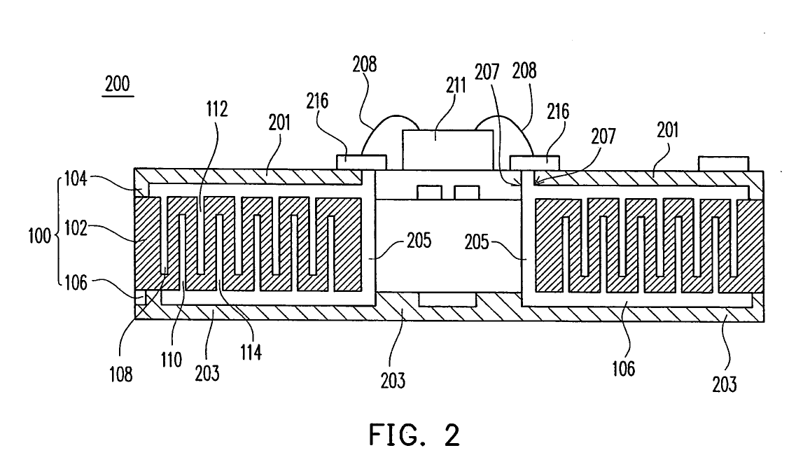

Referring to FIG. 2, FIG. 2 is a cross-sectional view of a package structure of an interlayer circuit board 200 having the package structure 100 with the embedded capacitor according to one embodiment of the present invention. In the present embodiment, the package structure 100 with the embedded capacitor can serve as the core layer of the interlayer circuit board 200. The first conductive layer 104 and the second conductive layer 106 in the core layer are covered by a second dielectric layer 201 and a third dielectric layer 203 respectively. The first conductive layer 104 and the second conductive layer 106 are conducted with each other through an interconnecting line 205 which penetrates the dielectric layer 102 and the second dielectric layer 201.

In the present embodiment, the second dielectric layer 201 and the third dielectric layer 203 are constituted by a solder mask. However, in a different embodiment, the second dielectric layer 201 and the third dielectric layer 203 are vertically laminated layers constituted by a dielectric material. Through blind vias, the blind via 207 for example, formed on the second dielectric layer 201, the area where the first conductive layer 104 is electrically connected with an outer electronic device (e.g. a chip 211) is exposed. Exposed portions of the first conductive layer 104 and a top surface of the interconnecting line 205 are respectively covered by a metallic covering layer 216, which can serve as a pad for electrically connecting a bonding wire 208 with the outer electronic device (e.g. the chip 211) in a subsequent wire bonding process or in a flip chip package process.

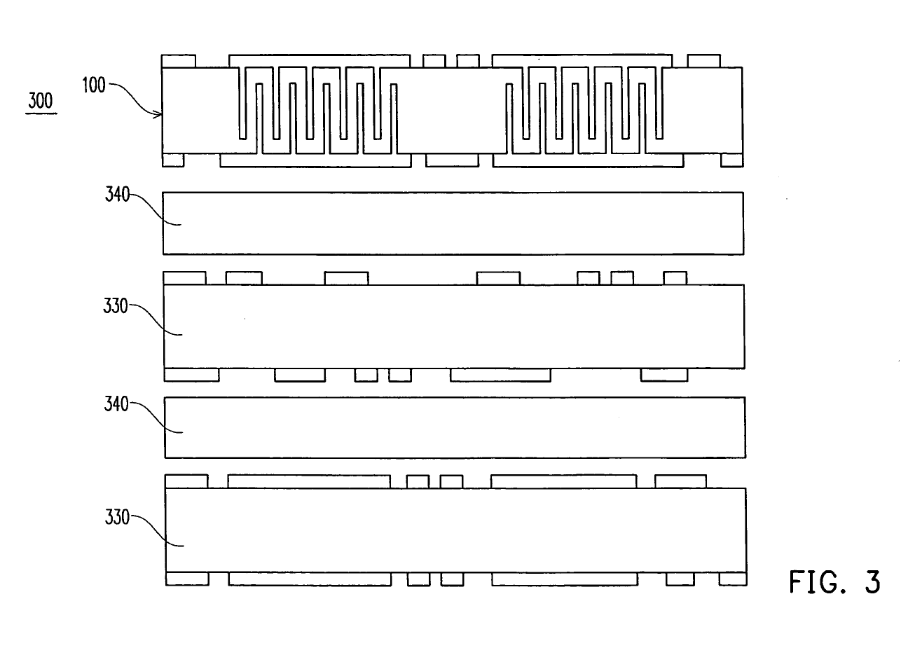

Referring to FIG. 3, FIG. 3 illustrates a cross-sectional view of a package structure 300 with a multi-layered circuit board 300 having the package structure 100 of the embedded capacitor according to another embodiment of the present invention. In the present embodiment, the package structure 300 of the stacked circuit board is formed by laminating a plurality of core substrates 330 and a plurality of dielectric layers 340. The package structure 100 of the embedded capacitor can serve as one of laminated layers in the package structure 300 of the multi-layered circuit board.

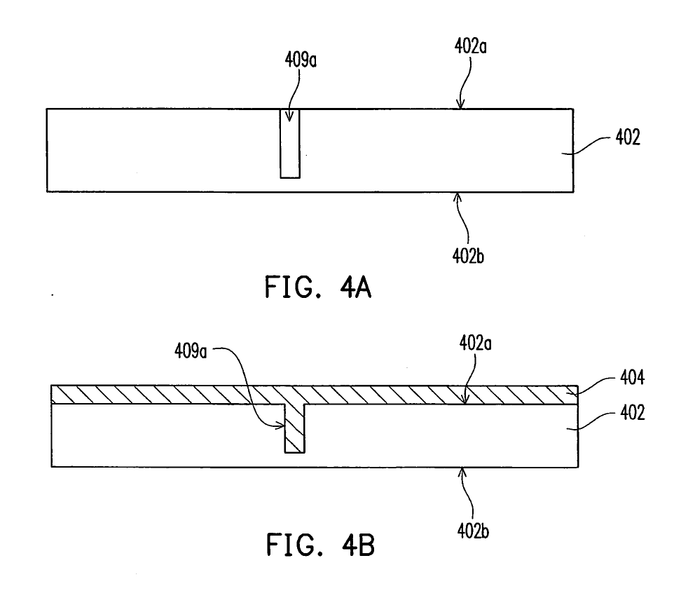

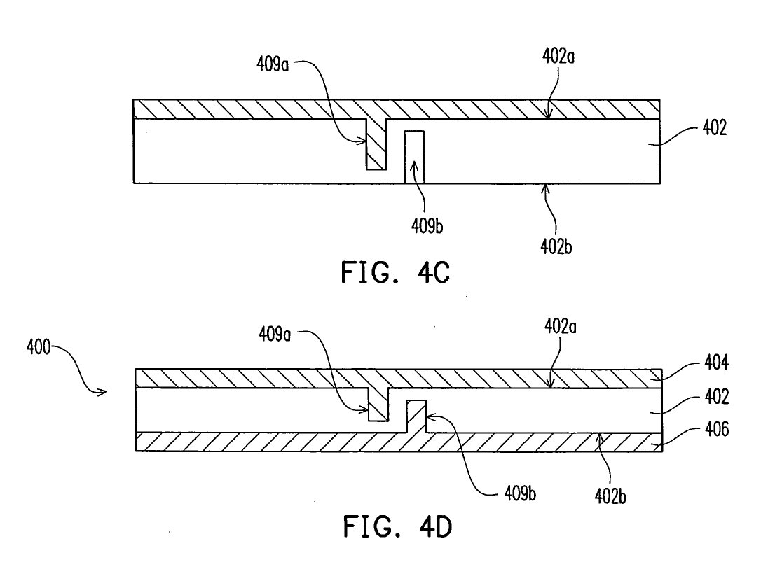

Referring to FIGS. 4A-4D, FIGS. 4A-4D are cross-sectional views illustrating a processing flow for fabricating a package structure 400 with an embedded structure according to one embodiment of the present invention. The fabricating process for forming the package structure 400 with the embedded capacitor includes steps as follows.

A dielectric layer 402 is provided at first. Next, a first surface 402a of the dielectric layer 402 is patterned for forming a first groove 409a (referring to FIG. 4A). Then, a first conductive layer 404 is formed on the first surface 402a, and the first groove 409a is filled with the first conductive layer 404 (referring to FIG. 4B). After that, a second surface 402b of the dielectric layer 402 is patterned for forming a second groove 409b, wherein the second surface 402b is opposite to the first surface 402a, and the first groove 409a is separated from the second groove 402b at a distance (referring to FIG. 4C). Thereafter, a second conductive layer 406 is formed on the second surface 402b, and the second groove 409b is filled with the second conductive layer 406.

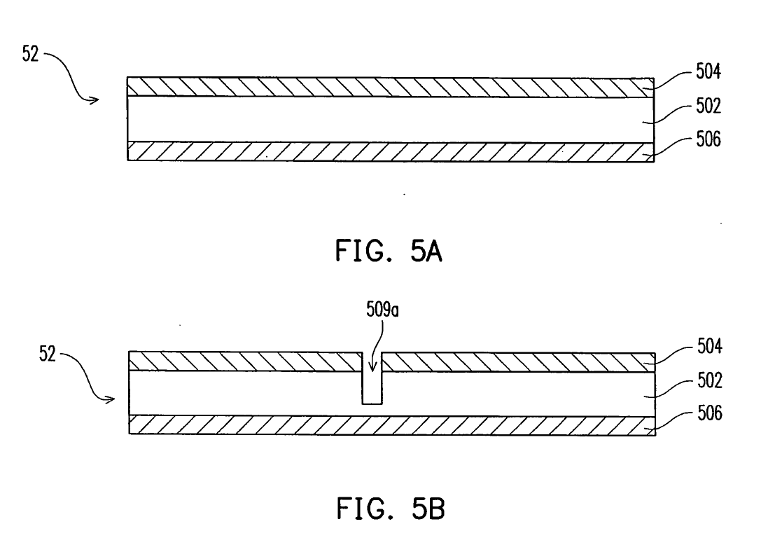

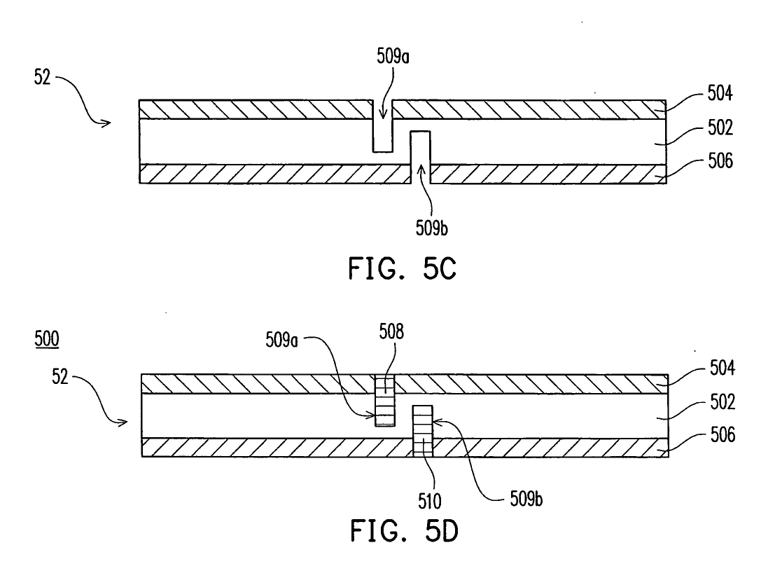

Referring to FIGS. 5A-5D, FIGS. 5A-5D are cross-sectional views illustrating a processing flow for fabricating a package structure 500 with an embedded structure according to another embodiment of the present invention. The fabricating process for forming the package structure 500 with the embedded capacitor includes steps as follows.

A core layer 52 is provided at first, wherein the core layer 52 includes a substrate 502 constituted by a dielectric material, a first conductive layer 504 disposed at one side of the substrate 502, and a second conductive layer 506 disposed on the substrate 502 at the other side thereof opposite to the first conductive layer 504 (referring to FIG. 5A). Next, a first groove 509a is formed on the first conductive layer 504, and the first groove 509a is recessed in the dielectric substrate 502 (referring to FIG. 5B). Then, a second groove 509b is formed on the second conductive layer 506 and recessed in the dielectric substrate 502. The first groove 509a is separated from the second groove 509b at a distance (referring to FIG. 5C). After that, the first groove 509a and the second groove 509b are filled with a conductive material for forming a first embedded plate 508 and a second embedded plate 510 (referring to FIG. 5D).

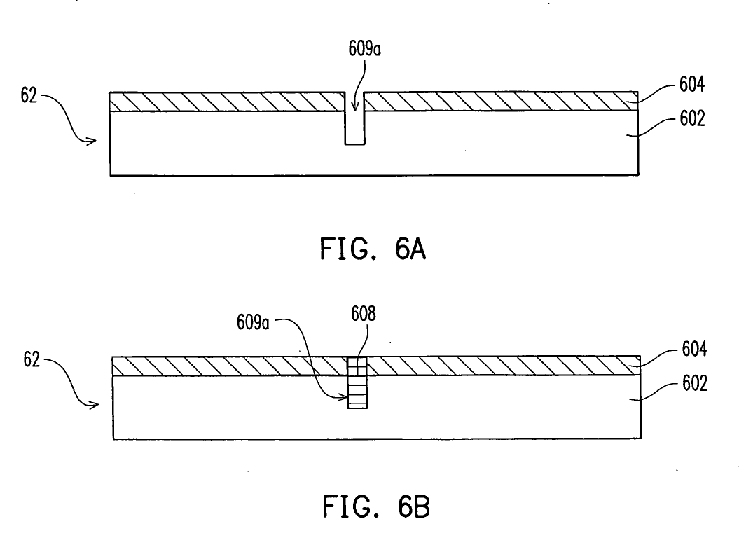

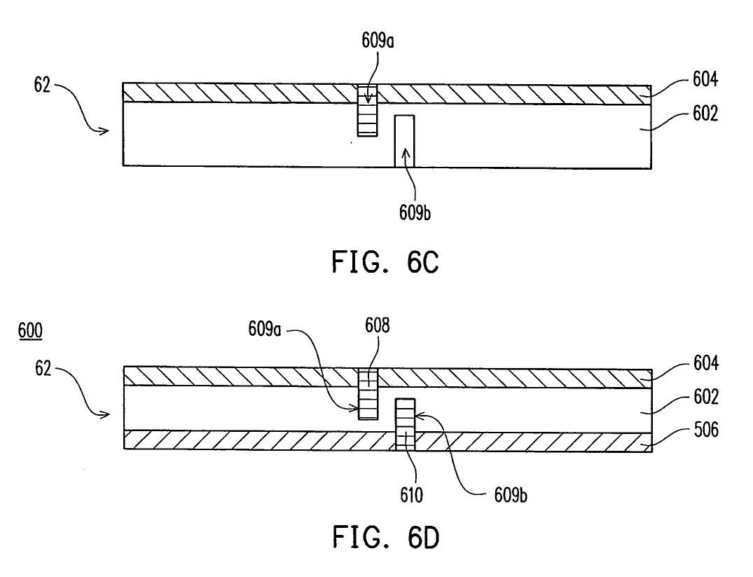

Referring to FIGS. 6A-6D, FIGS. 6A-6D are cross-sectional views illustrating a processing flow for fabricating a package structure 600 with an embedded structure according to one embodiment of the present invention. The fabricating process for forming the package structure 600 with the embedded capacitor includes steps as follows.

An RCC layer 62 is provided at first, wherein the RCC layer 62 includes a resin substrate 602 and a copper film 604 which is disposed at one side of the resin substrate 602. Next, a first groove 609a is formed on the copper film 604, and the first groove 609a is recessed in the resin substrate 602 (referring to FIG. 6A). After that, the first groove 609a is filled with a conductive material for forming a first embedded plate 608 (referring to FIG. 6B). Thereafter, a second groove 609b is formed and recessed in the resin substrate 602, and the first groove 609a is separated from the second groove 609b at a distance (referring to FIG. 6C). Then, a second conductive layer 606 is formed on the resin substrate 602 at the other side thereof opposite to the copper film 604, and the second groove 609b is filled with the second conductive layer 606 for forming a second embedded plate 610 (referring to FIG. 6D).

In one embodiment of the present invention, the techniques of the present invention are characterized in that the two grooves formed respectively at the opposite sides of the dielectric layer (the substrate) are filled with the conductive material for forming the conductive embedded plates correspondingly embedded in the dielectric layer, and the two embedded plates are conducted with the first conductive layer and the second conductive layer respectively. Moreover, the package structure with the embedded capacitor can be formed by the two conductive embedded plates with the opposite potentials, and by the dielectric layer between the two conductive embedded plates.

The two embedded plates are directly embedded in a single dielectric layer, and therefore, even the number or the density of the embedded plates increases for enhancing the capacitor property of the embedded capacitor, it is unnecessary to increase the number of the stacked dielectric layers and thereby preventing a significant increase in the thickness of the package structure.

Therefore, by using the aforesaid embodiments, not only a circuit layout of the package structure is shortened, but also a distance of signal transmission is reduced for saving the layout space, and thereby the package structure with the embedded capacitor has an advantage that the thickness of the package structure does not need to be increased, so as to solve the problem that a thickness of the substrate has to be increased significantly for improving the working efficiency of a conventional embedded capacitor. Besides, because the embedded plates which have a same potential and form the embedded capacitor are formed at a same side of the dielectric layer, and therefore they can be fabricated in a single fabricating process, and thereby the package structure is relatively simple in comparison with that of the conventional embedded capacitor, and the process complexity and the process cost can be reduced.

It will be apparent to those skilled in the art that various modifications and variations can be made to the present invention without departing from the scope or spirit of the invention. In view of the foregoing, it is intended that the present invention cover modifications and variations of this invention provided they fall within the scope of the following claims and their equivalents.

What is claimed is:

1. A package structure with an embedded capacitor, comprising:
a dielectric layer having a thickness;
a first conductive layer disposed at one side of the dielectric layer, wherein the first conductive layer has a first potential;
a second conductive layer disposed on the dielectric layer at the other side thereof opposite to the first conductive layer, wherein the second conductive layer has a second potential;
a first embedded plate embedded in the dielectric layer and electrically connected with the first conductive layer; and
a second embedded plate embedded in the dielectric layer, electrically connected with the second conductive layer and separated from the first embedded plate at a distance.

2. The package structure with the embedded capacitor according to claim 1, wherein the first embedded plate and the second embedded plate are respectively embedded in the dielectric layer with a length larger than half of the thickness of the dielectric layer.

3. The package structure with the embedded capacitor according to claim 1, wherein the first conductive layer and the first embedded plate form a first included angle that is substantially larger than 0 degree and smaller than 180 degrees.

4. The package structure with the embedded capacitor according to claim 3, wherein the first included angle is 90 degrees.

5. The package structure with the embedded capacitor according to claim 1, wherein the second conductive layer and the second embedded plate form a second included angle that is larger than 0 degree and smaller than 180 degrees.

6. The package structure with the embedded capacitor according to claim 5, wherein the second included angle is 90 degrees.

7. The package structure with the embedded capacitor according to claim 1, wherein the first embedded plate is parallel to the second embedded plate.

8. The package structure with the embedded capacitor according to claim 1, further comprising:
a third embedded plate embedded in the dielectric layer and electrically connected with the first conductive layer, wherein the second embedded plate is disposed between the first embedded plate and the third embedded plate, and three of them are separated from one another at a distance; and
a fourth embedded plate embedded in the dielectric layer and electrically connected with the second conductive layer, wherein the third embedded plate is disposed between the second embedded plate and the fourth embedded plate, and three of them are separated from one another at a distance.

9. The package structure with the embedded capacitor according to claim 8, wherein the first embedded plate, the second embedded plate, the third embedded plate and the fourth embedded plate are parallel to one another.

10. A core layer of a package structure, comprising:
a substrate having a thickness;
a first conductive layer disposed at one side of the substrate and having a first potential;
a second conductive layer disposed on the substrate at the other side thereof opposite to the first conductive layer, wherein the second conductive layer has a second potential;
a first embedded plate embedded in the substrate and electrically connected with the first conductive layer; and
a second embedded plate embedded in the substrate, electrically connected with the second conductive layer and separated from the first embedded plate at a distance.

11. The core layer of the package structure according to claim 10, wherein the first embedded plate and the second embedded plate are respectively embedded in the dielectric layer with a length larger than half of a thickness of the dielectric layer.

12. The core layer of the package structure according to claim 10, wherein the first conductive layer and the first embedded plate form a first included angle that is larger than 0 degree and smaller than 180 degrees.

13. The core layer of the embedded capacitor according to claim 12, wherein the first included angle is 90 degrees.

14. The core layer of the package structure according to claim 10, wherein the second conductive layer and the second embedded plate form a second included angle that is larger than 0 degree and smaller than 180 degrees.

15. The core layer of the embedded capacitor according to claim 14, wherein the second included angle is 90 degrees.

16. The core layer of the package structure according to claim 10, wherein the first embedded plate is parallel to the second embedded plate.

17. The core layer of the package structure according to claim 10, further comprising:
a third embedded plate embedded in the substrate and electrically connected with the first conductive layer, wherein the second embedded plate is disposed between the first embedded plate and the third embedded plate, and three of them are separated from one another at a distance; and
a fourth embedded plate embedded in the dielectric layer and electrically connected with the second conductive layer, wherein the third embedded plate is disposed between the second embedded plate and the fourth embedded plate, and three of them are separated from one another at a distance.

18. The core layer of the package structure according to claim 17, wherein the first embedded plate, the second embedded plate, the third embedded plate and the fourth embedded plate are parallel to one another.

19. A fabricating process of a package structure with an embedded capacitor, comprising:
providing a dielectric layer;
patterning a first surface of the dielectric layer to form a first groove in the dielectric layer;
forming a first conductive layer on the first surface and filling the first groove with the first conductive layer;
patterning a second surface of the dielectric layer to form a second groove in the dielectric layer, wherein the second surface is opposite to the first surface, and the first groove is separated from the second groove at a distance; and
forming a second conductive layer on the second surface and filling the second groove with the second conductive layer.

20. A fabricating process of a package structure with an embedded capacitor, comprising:
providing a core layer, wherein the core layer comprises:
a substrate;
a first conductive layer disposed at one side of the substrate; and
a second conductive layer disposed on the substrate at the other side thereof opposite to the first conductive layer;
forming a first groove on the first conductive layer wherein the first groove is recessed in the substrate;
forming a second groove on the second conductive layer wherein the second groove is recessed in the substrate and the first groove is separated from the second groove at a distance; and
filling the first groove and the second groove with a conductive material.

21. A fabricating process of a package structure with an embedded capacitor, comprising:
providing a resin clad copper (RCC) layer, wherein the RCC layer comprises a substrate and a copper film disposed at one side of the substrate;
forming a first groove on the copper film, wherein the first groove is recessed in the substrate;
filling the first groove with a conductive material;
forming a second groove recessed in the substrate at the other side thereof opposite to the copper film, the first groove being separated from the second groove at a distance; and
forming a second conductive layer on the substrate at one side thereof opposite to the copper film, and filling the second groove with the second conductive layer.
